(19) United States
(12) Patent Application Publication
(10) Pub. No.: US 2006/0104033 A1
(43) Pub. Date: May 18, 2006

(54) Connection structure of thermal tube and heat dissipation fins

(76) Inventors: Chih-Chiang Yeh, Hsinchu City (TW); Frederick Lee, Hsinchu City (TW)

Correspondence Address: LEONG C LEI, PMB # 1008, 1867 YGNACIO VALLEY ROAD, WALNUT CREEK, CA, 94598, US

(21) Appl. No.: 10/986,369

(22) Filed: Nov. 12, 2004

(51) Int. Cl. H05K 7/20

(52) U.S. Cl. 361/703

(57) ABSTRACT

A connection structure of thermal tube and heat dissipation fins is disclosed. The connection structure comprises thermal tube made from copper or aluminum and heat dissipation fins made from metal, the fins having through holes from the installation of thermal tube as a unit, characterized in that any of the surface of the thermal tube or the heat dissipation fins is provided with a low melting point metal layer, thereby the low melting thermal tube (or the dissipation fins) via appropriate heating process can point metal layer of the combined unit of the effectively fill the gap of the connection surface between the thermal tube and the heat dissipation fins. The connection of the thermal tube and the heat dissipation fins is firm and the conductivity is excellent.

### BACKGROUND OF THE INVENTION

(a) Technical Field of the Invention

The present invention relates to connection structure, and in particular, a connection structure of thermal tube and heat dissipation fins. The connection face of the thermal tube and the fins are firmly secured and the heat conductivity is stable.

(b) Description of the Prior Art

Taiwanese Utility Model Publication No. 332681 entitled “Thermal Tube And Heat Dissipation Fins As One Unit” discloses the enhanced connection of heat dissipation fins and the thermal tube. However, after long period of application, the area of coating of tin solder at the gap between the heat dissipation fins and the thermal tube cannot be effectively control. Thus, the sealing quality is not stable.

Generally, the technology of mounting the heat dissipation fins onto a thermal tube to improve heat dissipation area of the thermal tube in common. The most commonly used material for the thermal tube and the heat dissipation fins are copper or aluminum. However, the firmness between the binding area of the thermal tube and the heat dissipation fin directly affects the heat conductivity. Thus, it is an important technique to effectively improved the binding area between the thermal tube and the heat dissipation fins.

A conventional type of connection of the thermal tube and the heat dissipation fins is the connection of fins at the through holes provided to the fins.

The binding surface between each of the heat dissipation fins is difficult to control, and therefore gaps will form at the binding area, and the heat conductivity is reduced. In addition, due to inappropriate external compression or impact, the positions of the heat dissipation fins may not at the right position.

Accordingly, it is an object of the present invention is to provide a connection structure of thermal tube and heat dissipation fins which mitigates the above drawbacks.

### SUMMARY OF THE INVENTION

Accordingly, it is an object of the present invention to provide a connection structure of thermal tube and heat dissipation fins, wherein the connection structure comprises thermal tube made from copper or aluminum and heat dissipation fins made from metal, the fins having through holes from the installation of thermal tube as a unit, characterized in that any of the surface of the thermal tube or the heat dissipation fins is provided with a low melting point metal layer, thereby the low melting thermal tube (or the dissipation fins) via appropriate heating process can point metal layer of the combined unit of the effectively fill the gap of the connection surface between the thermal tube and the heat dissipation fins.

Yet another object of the present invention is to provide a connection structure of thermal tube and heat dissipation fins, wherein the connection of the thermal tube and the heat dissipation fins is firm and the conductivity is excellent.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a front view of the first preferred embodiment before combination of the present invention.

FIG. 2 is a perspective view of the first preferred embodiment in accordance with the present invention.

FIG. 3 is a side view of the first preferred embodiment in accordance with the present invention.

FIG. 4 is a sectional view showing the low melting point metal layer of the present invention.

FIG. 5 is a sectional view showing the filling of the gap of the connection area after the melting of the low melting point metal layer of the present invention.

FIG. 6 is a perspective view of a second preferred embodiment of the present invention.

FIG. 7 is a perspective view of a third preferred embodiment of the present invention.

### DETAILED DESCRIPTION OF THE PREFERRED EMBODIMENTS

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

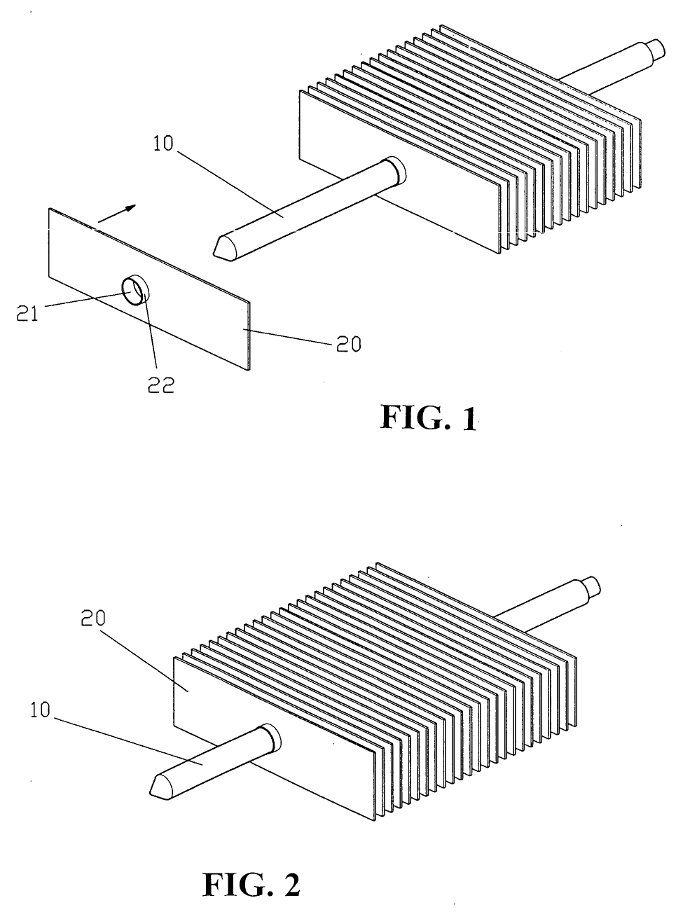

FIGS. 1 and 2 show the connection structure of the thermal tube and fins comprising a copper or aluminum made thermal tube 10, and any metallic made heat dissipation fins 20. The fins 20 are provided with through holes 21. The opening edge at one end of the through hole is extended to form a circular connection section 22. The internal diameter of the connection 22 and the external diameter of the thermal tube 10 can be interconnected.

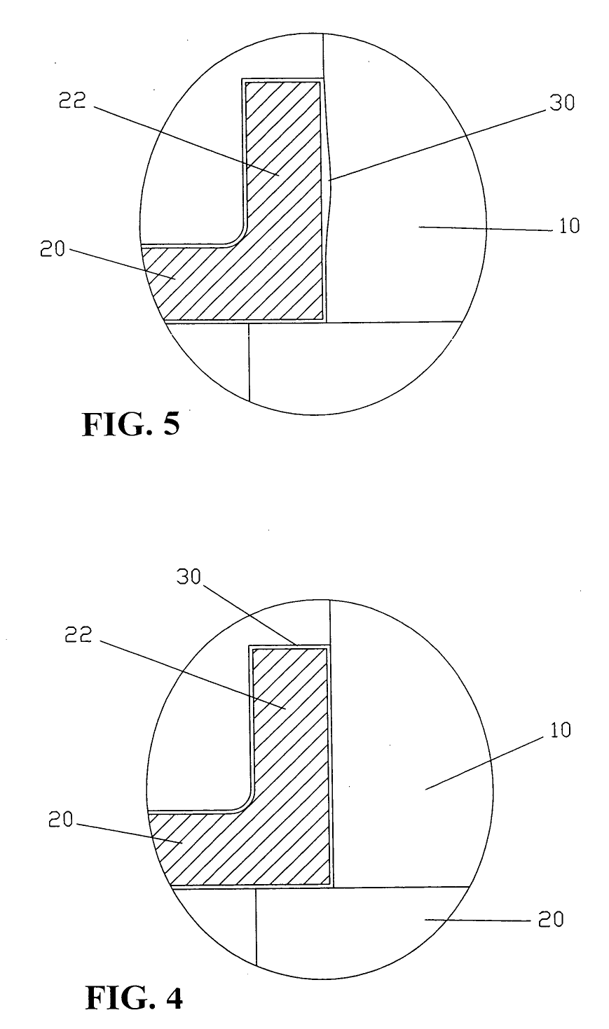

Referring to FIGS. 1 and 4, there is shown the connection structure including the thermal tube 10 or any surface of the heat dissipation fins 20, wherein electroplating process or chemical deposition method is used to deposit a low melting point metal layer 30, for instance, tin, selenium.

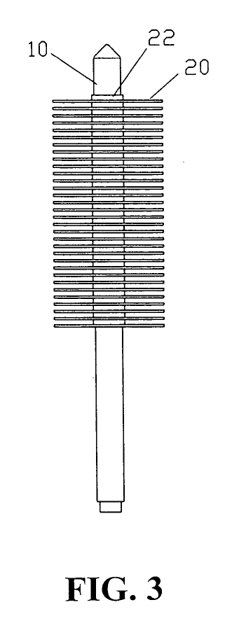

As shown in FIGS. 2 and 3, when the heat dissipation fins 20 are mounted onto the thermal tube 10 based on the required number of fins and space, heating process is employed to fuse the low melting point metal layer 30.

Referring to FIGS. 4 and 5, all the gaps of the contact surface area between the thermal tube 10 and the heat dissipation fins 20 are filled by the low melting point metal layer 30 such that the connection surface area is fully adhered or bound. Thus, the thermal resistance due to gaps formation is effectively reduced.

### Preferred Embodiment 2

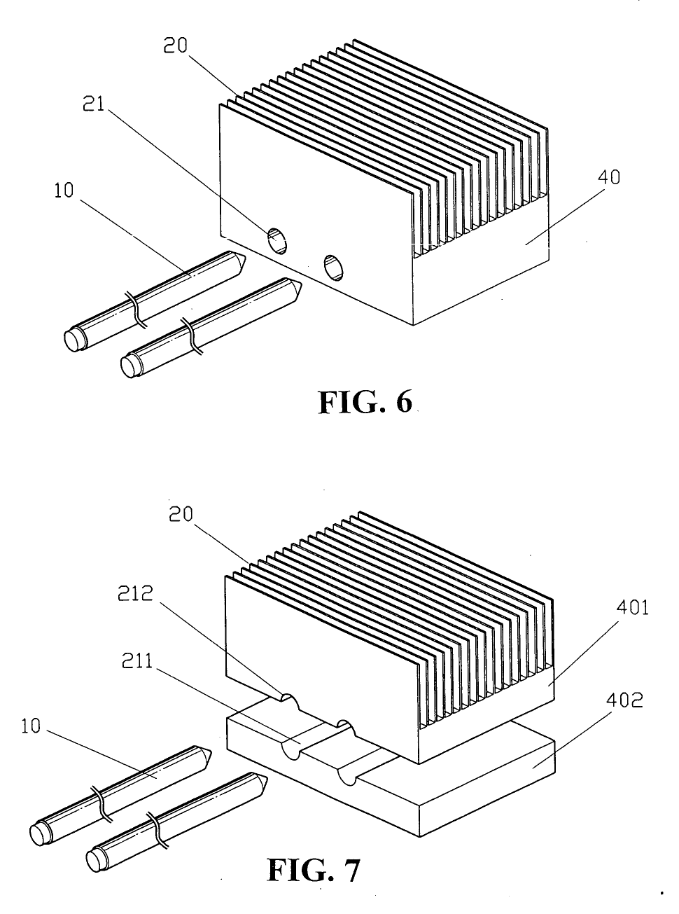

Referring to FIG. 6, the connection structure of the thermal tube and the heat dissipation fins is shown which include copper or aluminum made thermal tube 10, and heat dissipation fins 20 made from any metal. The heat dissipation fins 20 forms with the heat sink 10 as one unit, and one side of the heat sink is provided with through hole 21 for mounting with the thermal tube 10.

Before the thermal tube 10 and the heat dissipation fins 20 are combined, any of the fins 20 surface or the thermal tube 10, or the connection surface, is coated with a low melting point metal layer using electroplating or chemical deposition method. One end of the thermal tube 10 is mounted into the through holes 21 of the heat sink from one end, and a heating process is applied to the low melting point metal layer. All the gaps of the contact surface of the thermal tube 10 and the through hole 21 will be filled by the melted low melting point metal layer. Thus the firmness of the connection is obtained.

### Preferred Embodiment 3

There is shown another preferred embodiment of connection structure between the thermal tube and the heat dissipation fins. As shown in FIG. 7, the copper or aluminum made thermal tube 10 and any metal made heat dissipation fins 20 are connected, wherein the heat dissipation fins 20 form on the heat sink upper layer 401 to form one unit. Between the connection face of the upper layer 401 and lower layer 402 of the heat sink there are semicircular slots 211, 212 for the holding of the thermal tube 10. As shown in the above structure, the thermal tube 10 or the surface of the heat dissipation fins 20 are combined, and electroplating or chemical deposition method is employed to coat a low melting point metal layer, and the thermal tube 10 is placed between the semicircular slots 211, 212. An appropriate heating process is employed to melt the low melting point metal layer so that all the gaps of the contact surface of the thermal tube 10 and the heat dissipation fins 20 are filled. Thus, the firmness of the connection is obtained.

In accordance with the above preferred embodiment, electroplating method on chemical deposition method is employed to adhere a low melting point metal layer 30 onto the thermal tube 10 or the surface of the heat dissipation fins 20. Additional metals include Nickle or Silver can be used for coating to the thermal tube and/or the heat dissipation fins. As low temperature heating process is employed, there is a low requirement or energy.

While the invention has been described with respect to preferred embodiments, it will be clear to those skilled in the art that modifications and improvements may be made to the invention without departing from the spirit and scope of the invention. Therefore, the invention is not to be limited by the specific illustrative embodiment, but only by the scope of the appended claims.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A connection structure of thermal tube and heat dissipation fins comprising thermal tube made from copper or aluminum and heat dissipation fins made from metal, the fins having through holes from the installation of thermal tube as a unit, characterized in that any of the surface of the thermal tube or the heat dissipation fins is provided with a low melting point metal layer, thereby the low melting point metal layer of the combined unit of the thermal tube (or the dissipation fins) via appropriate heating process can effectively fill the gap of the connection surface between the thermal tube and the heat dissipation fins.

2. The connection structure of claim 1, wherein the low melting point metal layer is selected from the group consisting of tin, selenium, bismuth, polonium, pure metal or alloy.

3. The connection structure of claim 1, wherein the low melting point metal layer is electroplated onto or by chemical deposition method onto the thermal tube or any surface of the heat dissipation fins before combination.

4. The connection structure of claim 1, wherein the heat dissipation fin made from either copper material or aluminum material.

5. The connection structure of claim 1, wherein the heat dissipation fins are formed as a unit on a heat sink, and the holes on the fins are formed at one lateral side of the heat sink.
